(19) United States
(12) Patent Application Publication
(10) Pub. No.: US 2017/0352569 A1
(43) Pub. Date: Dec. 7, 2017

(54) ELECTROSTATIC CHUCK HAVING PROPERTIES FOR OPTIMAL THIN FILM DEPOSITION OR ETCH PROCESSES

(71) Applicant: Applied Materials, Inc., Santa Clara, CA (US)

(72) Inventors: Abdul Aziz KHAJA, San Jose, CA (US); Xing LIN, San Jose, CA (US); Edward P. HAMMOND, IV, Hillsborough, CA (US); Juan Carlos ROCHA-ALVAREZ, San Carlos, CA (US); Chidambara A. RAMALINGAM, Fremont, CA (US); Ganesh BALASUBRAMANIAN, Sunnyvale, CA (US); Ren-Guan DUAN, Fremont, CA (US); Jianhua ZHOU, Campbell, CA (US); Jonathan J. STRAHLE, San Francisco, CA (US)

(21) Appl. No.: 15/612,054

(22) Filed: Jun. 2, 2017

Related U.S. Application Data
(60) Provisional application No. 62/358,204, filed on Jul. 5, 2016.
(60) Provisional application No. 62/346,352, filed on Jun. 6, 2016.

(51) Int. Cl. H01L 21/683; H01L 21/67

(52) U.S. Cl. CPC H01L 21/6833; H01L 21/67103

(57) ABSTRACT

A heated support assembly is disclosed which includes a body comprising aluminum nitride doped with magnesium oxide having a volume resistivity of about 1×10¹⁰ Ω-cm at about 600 degrees Celsius, an electrode embedded in the body, and a heater mesh embedded in the body.

### CROSS-REFERENCE TO RELATED APPLICATIONS

This application claims benefit of U.S. Provisional Patent Application Ser. No. 62/346,352, filed Jun. 6, 2016 (Attorney Docket 24214USL) and U.S. Provisional Patent Application Ser. No. 62/358,204, filed Jul. 5, 2016 (Attorney Docket 24214USL02), both of which are hereby incorporated herein by reference.

### BACKGROUND

### Field

Embodiments of the disclosure generally relate to an electrostatic chuck having physical properties and design that enhance thin film deposition uniformity and/or uniformity in etch processes.

### Description of the Related Art

Integrated circuits have evolved into complex devices that can include millions of components (e.g., transistors, capacitors, resistors, and the like) on a single chip. The evolution of chip designs requires faster circuitry as well as greater circuit density, and the demand for greater circuit density necessitates a reduction in the dimensions of the integrated circuit components. The minimal dimensions of features of such devices are commonly referred to in the art as critical dimensions. The critical dimensions generally include the minimal widths of the features of the circuit structure, such as lines, spaces between the lines, columns, openings, and the like.

As these critical dimensions shrink, process uniformity across the substrate becomes important in order to maintain high yields. While processing chambers utilized to form features on substrates may be substantially identical, subtle variations may exist between the processing chambers. The variations may require adjustment of the process parameters on one or more of the processing chambers to obtain “chamber match” or “chamber matching.” One problem associated with a conventional deposition process is non-uniformity in the deposited film. Another problem associated with conventional plasma etch processes is the non-uniformity of an etch rate across the substrate. Both of the aforementioned problems may be due, in part, to the design and physical properties of an electrostatic chuck which supports the substrate during the deposition or etch process. This non-uniformity may significantly affect performance and increase the cost of fabricating integrated circuits.

Accordingly, it is desirable to reduce the chamber-to-chamber variations in on-wafer results in order to streamline parallel processing of substrates.

### SUMMARY

A method and apparatus is disclosed including a heated electrostatic chuck having reduced diffusion of yttrium aluminate at the substrate receiving surface thereof.

In one embodiment, a heated support assembly is disclosed which includes a body comprising aluminum nitride doped with magnesium oxide having a volume resistivity of about 1×10¹⁰ Ω-cm at about 600 degrees Celsius, an electrode embedded in the body, and a heater mesh embedded in the body.

In another embodiment, a method for making a heated support assembly is disclosed and includes providing a green body consisting essentially of aluminum nitride doped with yttrium oxide, embedding an electrode in the green body, positioning the green body in a mold, and heating the green body to a sintering temperature while compressing the green body.

In another embodiment, a method for making a heated support assembly is disclosed and includes providing a green body consisting essentially of aluminum nitride doped with yttrium oxide, embedding an electrode in the green body, positioning the green body in a mold, and heating the green body to a sintering temperature below about 2,000 degrees Celsius while compressing the green body.

In another embodiment, a heated support assembly is provided and includes a body, an embedded electrode provided in the body, and a substrate receiving surface consisting essentially of aluminum nitride doped with yttrium oxide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial cross-sectional view showing an illustrative processing chamber having a support assembly according to embodiments disclosed herein.

FIG. 2 is a schematic sectional view of a sintering apparatus for forming the support assembly of FIG. 1.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure provide an electrostatic chuck that may be used in a processing chamber for any number of substrate processing techniques is provided. The electrostatic chuck is particularly useful for performing plasma assisted dry etch processing that requires both heating and cooling of the substrate surface without breaking vacuum. Additionally, the electrostatic chuck may be useful for performing a thin film deposition process on a substrate. The electrostatic chuck as described herein may be utilized in etch chambers from Applied Materials, Inc. of Santa Clara, Calif., but may also be suitable for use in chambers for other plasma processes as well as chambers from other manufacturers.

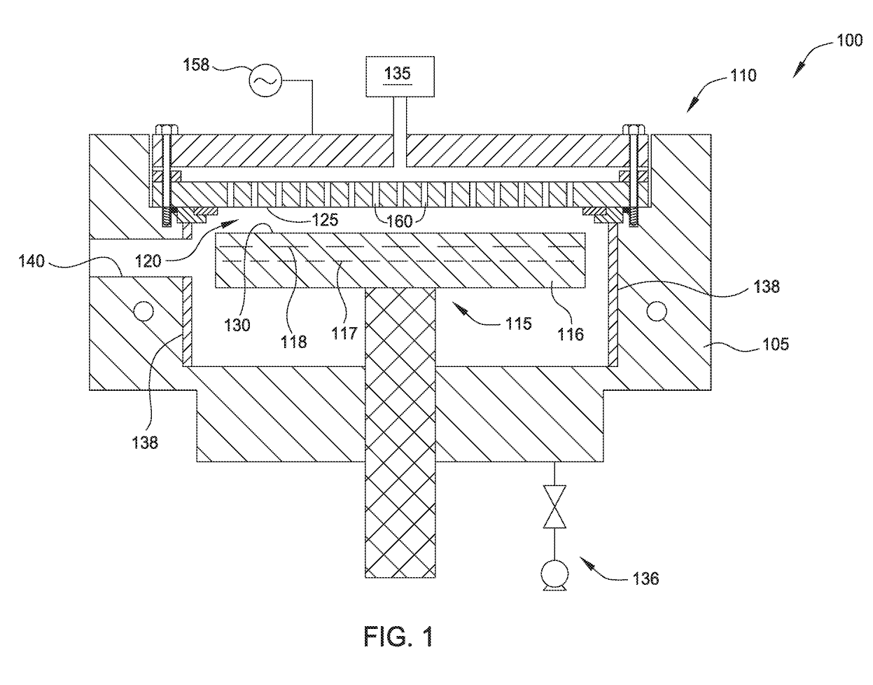

FIG. 1 is a partial cross-sectional view showing an illustrative processing chamber 100. The processing chamber 100 may be utilized in a etch process or a deposition process. In one implementation, the processing chamber 100 includes a chamber body 105, a gas distribution plate assembly 110, and a support assembly 115. The support assembly 115 is an electrostatic chuck 116 that includes a heater mesh 117 and an embedded electrode 118. The electrostatic chuck 116 may be made of an aluminum nitride (AlN) material doped with yttrium and the electrode 118 may be made of molybdenum (Mo). The chamber body 105 of the processing chamber 100 is preferably formed from one or more process-compatible materials, such as aluminum, anodized aluminum, nickel plated aluminum, nickel plated aluminum 6061-T6, stainless steel, as well as combinations and alloys thereof, for example.

The support assembly 115 may function as an electrode in conjunction with the gas distribution plate assembly 110 such that a plasma may be formed in a processing volume 120 between a perforated faceplate 125 and an upper surface 130 of the support assembly 115. The chamber body 105 may also be coupled to a vacuum system 136 that includes a pump and a valve. A liner 138 may also be disposed on surfaces of the chamber body 105 in the processing volume 120.

The chamber body 105 includes a port 140 formed in a sidewall thereof to provide access to the interior of the processing chamber 100. The port 140 is selectively opened and closed to allow access to the interior of the chamber body 105 by a wafer handling robot (not shown). A substrate (not shown) can be transferred in and out of the processing chamber 100 through the port 140 to an adjacent transfer chamber and/or load-lock chamber, or another chamber within a cluster tool. The support assembly 115 may be movable relative to the chamber body 105 such that the substrate, which may be processed on the upper surface 130 of the support assembly 115, may be in a position adjacent to the port 140, or a position in proximity to the perforated faceplate 125. The support assembly 115 may also be rotatable relative to the chamber body 105. Lift pins (not shown) may also be used to space the substrate away from the upper surface 130 of the support assembly 115 in a transfer process.

A radio frequency (RF) power source 158 may be coupled to the perforated faceplate 125 to electrically bias the gas distribution plate assembly 110 relative to the support assembly 115. The perforated faceplate 125 includes a plurality of openings 160 that are fluidly coupled to a process gas supply 135 to provide a gas to the processing volume 120.

Embodiments of the disclosure relate to the design and material properties of the aluminum nitride heater (i.e., the heated electrostatic chuck 116). The electrostatic chuck 116 is the major component of semiconductor substrate processing and may be used as either a RF hot or ground return in the processing chambers. The material properties of the electrostatic chuck 116 are often ignored and/or the design aspects of the electrostatic chuck 116 are not well specified. However, it has been found that the material properties and design aspects of the electrostatic chuck 116 play a critical role in film properties on a substrate.

There are multiple issues that are important when using aluminum nitride heaters, such as leakage current, RF mesh depth, and impedance. One or more of the aforementioned properties is very critical for matching chambers. Additionally, the material composition of the aluminum nitride heater is critical. A slight change in the composition will change the color of the heater under some conditions, which may also change the electrical properties of the heater. If the electrical properties of the heater changes then the plasma coupling to the substrate also changes. These properties are very much dependent on the type of process being run in a chamber.

Matching chambers that run identical processes is particularly critical for users migrating to more advanced nodes and 3D NAND structures. If the heater properties are not well controlled then the on-wafer results can vary heater-to-heater (i.e., chamber to chamber) causing a chamber matching issue. Also different processes have different sensitivities to heater properties as described herein.

For example, in an oxy nitride (ON) stack process, there has been observed a nitride stress mismatch of 70 MPa across multiple different chambers when the same recipe is run in these chambers. Electrostatic (ESC) current has a strong correlation to the stress (i.e., the leakage current across the heaters has a strong impact on stress).

One solution includes utilizing high voltage (e.g., about 1,000V) to improve the resolution of the leakage current measurement and tighten the specification. Alternatively, the heater temperature may be increased to about 650 degrees C. to have high leakage current.

In an oxy phosphide (OP) process there has been observed an oxide stress mismatch of 30 MPa across multiple different chambers when the same recipe is run in these chambers. There has also been observed an impedance mismatch of 15% at 350 kHz and 3% at 13.56 MHz between “good” and “bad” heaters. However, changing the low frequency RF power by 15 W has been observed to bring the stress back in specification. Another solution includes measuring the dielectric constant of the heater material and tightening the specification. Material density, thermal conductivity and volume resistivity impacts the performance of heater.

Testing of multiple pedestal heaters in a single chamber has shown a deposition rate variation between these multiple heaters. The depth of the heater mesh (the electrode 118) was found to be the biggest contributor to deposition rate variation (i.e., distance between the upper surface 130 of the support assembly 115 and the electrode 118). This distance/deposition rate variation has been observed to have a non-linear correlation.

Additionally, some lots of AlN heaters exhibit a discoloration from the normal grey color (e.g., “good” heaters). For example, some heaters have a pink color upon conditioning, cleaning and process cycles. Yttrium aluminate migrates towards the surfaces of the heater and has been shown to create a pink color in a hydrogen gas atmosphere. SEM/XRD Analysis indicates higher levels of Y-aluminates compared to available historical data and pink yttrium aluminate content higher than previously reported for AlN and the pink region has higher overall Y-aluminate contents.

Cross-sectional SEM images of conventional AlN heaters show non-uniform layers of AlN. An oxygen to yttrium (O/Y) ratio of a conventional heater is significantly reduced as compared to a new heater. Yttrium distribution and O/Y ratio are not uniform throughout the surface (specifically, center to edge).

Testing confirmed that the pink area only extends as far as the RF mesh (electrode 118). Further analysis suggested that the pink color thickness is about 500 microns so it is concluded that the discoloration is not surface deposition/film effect, instead it is due to bulk material. It is believed that the pink color in bulk crystalline material is due to color center formation, and color center is a vacancy (most likely an oxygen vacancy). In some heaters, the pink color is only on the outer zone location close to the outer diameter (periphery) of the electrostatic chuck 116.

It has been found that the discoloration of the AlN heater changes film properties during deposition. The mechanism for the discoloration may operate as follows: Y₂O₃ doping in AlN forms yttrium aluminate (like YAM (Y₄Al₂O₉)) and YAP (YAlO₃), that is located in a triangular area among AlN grains, and amorphous Y—Al—O—N is grain boundary. “Bad” pink colored heaters had more carbon diffused into the surface layer during sintering, and “good” heaters have less carbon on the surface layer. So a “good” heater had Y—Al—N—O grain boundary and a “bad” heater had Y—Al—NO—C grain boundary on the surface layer close to the outside diameter. In a reducing environment, oxygen in a “bad” heater surface grain boundary is easily lost from the grain boundary and an oxygen diffusion path is formed that leads to more oxygen removed from yttrium aluminate phase and oxygen vacancy (i.e., a pink color center) is formed.

Contrasting with a “good” heater, oxygen loss is difficult from Y—Al—N—O grain boundary and no oxygen vacancy is formed. The amount of carbon in the raw material influences the carbo-thermal reaction during sintering which changes the amount of Y AL or Y AM, Y AL being pre-dominantly on the grain boundaries. These components have a different reduction potential and if they show in the grain boundaries more abundantly it creates a transfer mechanism thru grain boundaries. Hence, the effectiveness of reduction increases versus being predominantly islands which are not linked together. In this scenario, the reduction species able to reduce a large area is not that high, hence a variation of pink in color. It is believed that the pink (“bad”) heater is an effect which is directly correlated to the leakage current (electrical properties) of the heater which impacts the film properties on a substrate. A solution is to control the incoming AlN material.

According to one implementation of the disclosure, a heated electrostatic chuck 116 may be formed with material properties and tighter specifications to suppress or eliminate yttrium aluminate formation.

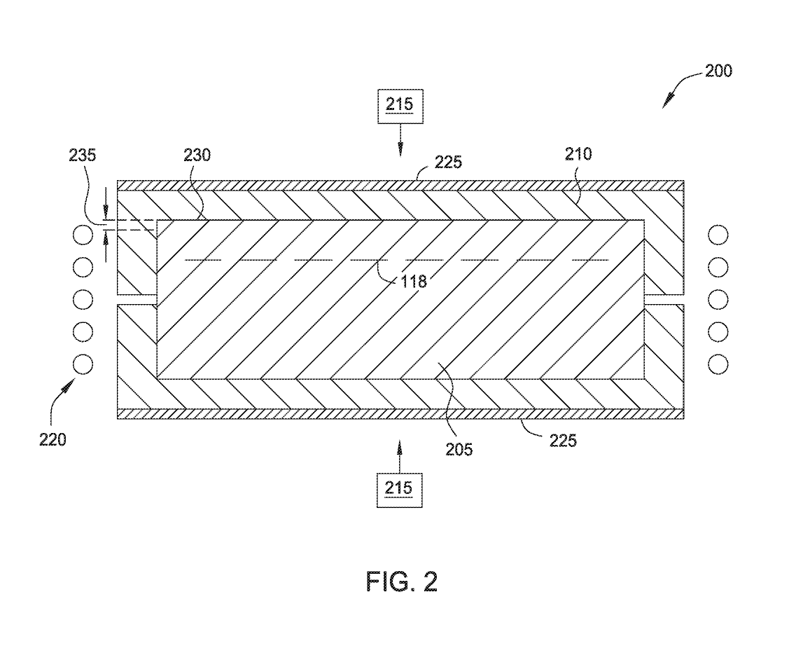

FIG. 2 is a schematic sectional view of a sintering apparatus 200 for forming the support assembly 115 of FIG. 1. A green body 205 comprising Y₂O₃ doped aluminum nitride is disposed in a mold 210 made of graphite. An electrode 118 is embedded in the green body 205. While not shown, a heater mesh 117 (shown in FIG. 1) may be embedded in the green body. Compression members 215 are disposed adjacent to major sides of the mold 210 and are configured to press the green body 205 while heating the mold 210 with a heater 220 at least partially surrounding the mold 210.

The sintering process is a key for ceramic properties. Y₂O₃ doped AlN sintering is a liquid phase sintering process. During the sintering process in the sintering apparatus 200, the sintering temperature needs to be kept as low as possible, and the sintering temperature variation needs to be narrowed. The higher the sintering temperature, the more liquid between grains may be formed and more yttrium aluminate may be diffused out. The sintering temperature needs to be controlled as low as possible while being hot enough to sinter in order to have less yttrium aluminate diffused out. This heating will maintain a similar material microstructure which keeps the properties of the final product similar. An example of low temperature is about 1,900 degrees C. to about 2,000 degrees C. with a small delta therebetween during the heating.

According to one implementation, the heater 220 is a high frequency inductive heater. High frequency inductive heating should to be used to prevent coupled heating of the Mo mesh (the electrode 118) that is co-sintered together with the AlN material. Yttrium aluminate may be diffused out from the Mo mesh area, so Mo mesh area is a high temperature area, this is due to coupled heating. An example of high frequency is a frequency greater than 60 Hz.

According to one implementation, thermal blockers are used on the top and bottom of the mold 210 to reduce thermal gradient and/or prevent thermal losses from the mold 210. Conventionally, the top and bottom of the mold 210 have the lowest temperature, so the temperature on these two locations needs to be improved in order to reduce thermal gradient that is a driving force for yttrium aluminate diffusion. An example of a thermal blocker is a ceramic material 225, in the form of a plate, film or coating, such as silicon nitride.

After sintering, the sintered green body 205 is machined to final dimensions. In conventional heaters, about 1 mm of material is removed from a surface 230 above the electrode 118. This surface 230 contains carbon diffused from the graphite mold 210. Additionally, due to the proximity of the electrode 118, the surface 230 may contain yttrium aluminate. According to one implementation, the surface 230 is machined to a depth 235 that is about 0.3 mm to about 0.5 mm greater than the material removed from conventional heaters after sintering (i.e., about 1.3 mm to about 1.5 mm).

In some conventional heaters, the material utilized for the electrostatic chuck 116 has a low volume resistivity at high temperatures. For example, conventional heaters made of AlN may have a volume resistivity of less than 2×10⁸ ohm-centimeters (Ω-cm) at above about 600 degrees Celsius. This may lead to a very high direct current (DC) leakage when high voltage is applied to the electrostatic chuck 116. The high DC leakage current of the conventional heaters may exceed about 50 milliamps. For example, heaters using conventional AlN materials have a leakage of more than about 50 milliamps (mA) at about 600 degrees Celsius when a chucking voltage of above about 500 volts DC. The high DC leakage current may result in system ground fault circuit interruption (GFCI) fault. The high DC leakage current may also increase the possibility of arcing which leads to device damage. Additionally, the conventional AlN materials tend to corrode in atmospheres having fluorine radicals at temperatures at about 550 degrees Celsius, which leads to AlFx particle generation.

In one implementation, the material utilized for the electrostatic chuck 116 includes an AlN with a magnesium oxide (MgO) additive. It was observed that the MgO additive promotes the densification of the AlN ceramic material. It reacts with Al₂O₃ on the surface AlN particles during sintering, and thus forms secondary phases that promote the densification at lower sintering temperatures leading to higher AlN volume resistivity. The reaction also generates a spinel (MgAl₂O₄) structure and glass phase, which may also reduce fluorine plasma corrosion. The increased volume resistivity of the AlN material used in the high temperature electrostatic chuck 116 results in reducing leakage current more than 30 times as compared to the conventional heaters. The electrostatic chuck 116 made of AlN with MgO additive has a volume resistivity of more than 1×10¹⁰ Ω-cm at about 600 degrees Celsius. A heater (e.g., electrostatic chuck 116) having AlN with MgO additive has been tested to show a leakage of less than about 10 mA at about 650 degrees Celsius when a chucking voltage of about 630 volts DC is applied. The reduced leakage current may provide for the use of a lower power DC power supply for applying a signal to the electrostatic chuck 116. Additionally, fluorine corrosion of the AlN with MgO additive material showed a reduced etch rate as compared to conventional heaters (a percentage decrease of about 40%) at 650 degrees Celsius, 0.1 Torr pressure, NF₃ radicals (at about 300 sccn) produced by 800 Watt RF power during a 5 hour test. After corrosion test, SEM microstructure demonstrated the heater with MgO additive had less surface damage than a conventional heater. Thermal conductivity of the AlN/MgO additive heater was compared with a conventional heater and found to be very close at 600 degrees Celsius. The AlN/MgO additive heater material includes Mg at about 0.6 weight percent. Other properties include a thermal conductivity of about 80 watts per meter Kelvin at about room temperature (e.g., about 21 degrees Celsius).

While the foregoing is directed to embodiments of the present disclosure, other and further embodiments of the disclosure may be devised without departing from the basic scope thereof, and the scope thereof is determined by the claims that follow.

1. A heated support assembly, comprising:
a body comprising aluminum nitride doped with magnesium oxide having a volume resistivity of about 1×10¹⁰ Ω-cm at about 600 degrees Celsius;
an electrode embedded in the body; and
a heater mesh embedded in the body.

2. The support assembly of claim 1, wherein the body has a magnesium oxide content of about 0.6 weight percent.

3. The support assembly of claim 1, wherein a surface of the body comprises a spinel (MgAl₂O₄) structure.

4. The support assembly of claim 1, wherein the body includes a thermal conductivity of about 80 watts per meter Kelvin at about room temperature.

5. The support assembly of claim 1, wherein the body has a leakage current of less than about 10 milliamps at about 650 degrees Celsius when a chucking voltage of about 630 volts direct current is applied thereto.

6. The support assembly of claim 1, wherein the volume resistivity is greater than about 1×10¹⁰ Ω-cm at about 600 degrees Celsius.

7. A method for fabricating a heated support assembly, comprising:
providing a green body consisting essentially of aluminum nitride doped with yttrium oxide;
embedding an electrode in the green body;
positioning the green body in a mold; and
heating the green body to a sintering temperature while compressing the green body.

8. The method of claim 7, wherein the heating comprises inductive heating.

9. The method of claim 8, wherein the inductive heating comprises a frequency of greater than 60 Hertz.

10. The method of claim 7, wherein the sintering temperature is below 2,000 degrees Celsius.

11. The method of claim 7, wherein a thermal blocker is provided on major sides of the mold during the heating and compressing.

12. The method of claim 7, wherein the thermal blocker comprises a ceramic material.

13. The method of claim 7, further comprising:
machining a surface of the body adjacent to the electrode to remove carbon and/or yttrium aluminate.

14. The method of claim 13, wherein about 1.3 mm to about 1.5 mm of the surface is removed during the machining.

15. The method of claim 13, wherein the surface is a grey color.

16. The method of claim 13, wherein the surface has a grain boundary consisting of yttrium-aluminum-nitrogen-oxygen.

17. A method for fabricating a heated support assembly, comprising:
providing a green body consisting essentially of aluminum nitride doped with yttrium oxide;
embedding an electrode in the green body;
positioning the green body in a mold; and
heating the green body to a sintering temperature below about 2,000 degrees Celsius while compressing the green body.

18. The method of claim 17, wherein a thermal blocker is provided on major sides of the mold during the heating and compressing.

19. The method of claim 18, wherein the thermal blocker comprises a ceramic material.

20. The method of claim 17, further comprising:
machining a surface of the body adjacent to the electrode to remove carbon and/or yttrium aluminate, wherein about 1.3 mm to about 1.5 mm of the surface is removed during the machining.
